(19) United States
(12) Patent Application Publication
(10) Pub. No.: US 2017/0104158 A1
(43) Pub. Date: Apr. 13, 2017

(54) VAPOR DEPOSITION METHOD AND VAPOR DEPOSITION APPARATUS

(71) Applicant: Sharp Kabushiki Kaisha, Sakai City, Osaka (JP)

(72) Inventors: Shinichi KAWATO, Sakai City (JP); Katsuhiro KIKUCHI, Sakai City (JP); Takashi OCHI, Sakai City (JP); Yuhki KOBAYASHI, Sakai City (JP); Kazuki MATSUNAGA, Sakai City (JP)

(21) Appl. No.: 15/315,849

(22) PCT Filed: Jun. 4, 2015
(86) PCT No.: PCT/JP2015/066221

§ 371 Date: Dec. 2, 2016

(30) Foreign Application Priority Data
Jun. 5, 2014 (JP) 2014-116936

(51) Int. Cl. H01L 51/00; C23C 14/12; H01L 51/56; C23C 14/24

(52) U.S. Cl. CPC H01L 51/0011; C23C 14/24; C23C 14/12; H01L 51/56; H01L 51/0012

(57) ABSTRACT

A vapor deposition apparatus includes: a vapor deposition source having a plurality of vapor deposition source apertures that emit vapor deposition particles; a restriction plate unit having a plurality of restriction apertures; and a vapor deposition mask in which a plurality of mask apertures are formed only within a plurality of vapor deposition regions at which vapor deposition particles passing through the plurality of restriction apertures arrive.

### TECHNICAL FIELD

The present disclosure relates to a vapor deposition method and apparatus for forming a film having a prescribed pattern on a substrate. The present disclosure also relates to an organic EL (Electro Luminescence) display device including a light-emitting layer formed by vapor deposition.

This application claims priority from Japanese Patent Application No. 2014-116936 filed in Japan on Jun. 5, 2014, and the entire contents of which are incorporated herein by reference.

### BACKGROUND ART

Organic EL display devices (displays) including organic EL elements include, for example, an active matrix organic EL display device. In this organic EL display device, thin-film-like organic EL elements are disposed on a substrate including TFTs (thin-film transistors). In each of the organic EL elements, an organic EL layer including a light-emitting layer is stacked between a pair of electrodes. A TFT is connected to one of the pair of electrodes. A voltage is applied between the pair of electrodes to cause the light-emitting layer to emit light. An image is thereby displayed.

A full-color organic EL display device generally includes organic EL elements including light-emitting layers of different colors, i.e., red (R), green (G), and blue (B), as sub-pixels formed and arranged on a substrate. TFTs are used to selectively cause these organic EL elements to emit light at a desired brightness, and a color image is thereby displayed.

To manufacture the organic EL display device, light-emitting layers formed of different organic light-emitting materials that emit light of different colors are formed into prescribed patterns for their respective organic EL elements by a vacuum deposition method.

In the vacuum deposition method, a mask (referred to also as a shadow mask) is used in which apertures arranged in a prescribed pattern are formed. The mask is brought into contact with and fixed to a substrate, and the substrate is disposed such that its deposition surface faces a vapor deposition source. Then vapor deposition particles (a film-forming material) from the vapor deposition source are deposited on the deposition surface through the apertures of the mask, and a film having the prescribed pattern is thereby formed. Vapor deposition is performed for each of the colors of the light emitting layers (this process is referred to as “color-patterned vapor deposition”).

The mask used is a metal mask (FMM: fine metal mask) having apertures formed with high precision, and different layers are vapor-deposited using this mask. Generally, vapor deposition is performed with the mask in contact with the substrate. However, the contact between the mask and the substrate causes many adverse effects and results in a reduction in precision.

The mask itself is attached to a frame under a very high tension. However, the following problems occur when the mask is brought into contact with the substrate.

First, the mask and the substrate spaced apart from each other are aligned within the apparatus. Then the mask and the substrate are brought into contact with each other. In this case, their behavior during contact varies depending on the tension balance of the mask itself, the physical sagging of the mask, etc. When the mask is a metal mask, the behavior varies depending on the strength of a magnet, the presence of foreign substances on the surface of the mask, etc. Therefore, the mask and the substrate may come into contact with each other at a position different from the desired alignment position. This misalignment is very difficult to control and causes a reduction in precision.

In RGB color patterning for a display, films of a plurality of colors are sequentially deposited. However, shielding portions of the mask may come into contact with the surfaces of previously deposited films, so that the film surfaces may be damaged. In this case, light-emitting characteristics may be adversely affected.

The thickness of the mask is very small, i.e., several tens of micrometers. When the mask is repeatedly brought into contact with and separated from the substrate during a plurality of vapor deposition processes, the mask suffers damage such as a reduction in tension, adhesion of foreign substances, etc. during every process. Particularly, when the mask is a high-definition mask, the damage is significant. This simply results in an increase in the number of times of washing and an increase in cost and also causes the fundamental reduction in precision described above.

One possible approach to solve the above problems is to space the substrate and the mask apart from each other. However, in this case, a vapor deposition pattern is broadened, and this causes a significant reduction in precision. One known method for addressing this issue is to improve the directivity of a vapor deposition beam (PTL 1).

### CITATION LIST

### Patent Literature

PTL 1: Japanese Unexamined Patent Application Publication No. 2004-103269

### SUMMARY

### Technical Problem

However, the above method does not restrict particles such that they arrive at the substrate from a unique direction, and the particles approach the substrate from various directions even with the above method. Therefore, the broadening of the vapor deposition pattern cannot be suppressed, and high-definition color patterning cannot be achieved. In other words, there has not been a vapor deposition method capable of appropriately preventing the broadening of the vapor deposition pattern with the mask and the substrate spaced apart from each other.

Some embodiments of the present invention are made in view of the above circumstances and are intended to achieve an object of providing a vapor deposition method and apparatus in which the spread angle of vapor deposition particles is restricted so that a high-definition pattern can be deposited with high productivity.

### Solution to Problem

A vapor deposition apparatus according to one aspect of the present invention is a vapor deposition apparatus for forming, on a substrate, a film through a vapor deposition mask having mask apertures formed therein, the film being formed into a pattern corresponding to an opening shape of the mask apertures. The vapor deposition apparatus includes: a vapor deposition unit including a vapor deposition source having at least one vapor deposition source aperture and a restriction plate unit having formed therein a plurality of restriction apertures through which vapor deposition particles emitted from the at least one vapor deposition source aperture pass; an alignment mechanism configured to align the substrate with the mask; and a moving mechanism configured to move one of the vapor deposition unit and a combination of the substrate and the mask aligned with each other relative to the other in a first direction, the first direction being one of in-plane directions of the substrate. The restriction apertures are disposed at positions on a side in a direction normal to the substrate with respect to the at least one vapor deposition source aperture and are perpendicular to the substrate. The restriction plate unit restricts the directivity, in the in-plane directions, of the vapor deposition particles directed toward the substrate. Specifically, the restriction plate unit restricts entry angles of vapor deposition particles emitted from the at least one vapor deposition source aperture and passing through the restriction apertures such that vapor deposition particles emitted from the at least one vapor deposition source aperture and passing through one of the restriction apertures enter a corresponding one of the mask apertures and that vapor deposition particles emitted from the at least one vapor deposition source aperture and passing through another one of the restriction apertures that is adjacent to the one of the restriction apertures do not arrive at the corresponding one of the mask apertures. Therefore, even when vapor deposition is performed with the mask and the substrate spaced apart from and not in contact with each other, the vapor deposition particles travel substantially straight in the normal direction, so that the film formed is prevented from being broadened with respect to the mask apertures.

A vapor deposition method according to one aspect of the present invention is a vapor deposition method in which vapor deposition particles are caused to adhere to a substrate through a vapor deposition mask having mask apertures formed therein to thereby form a film having a pattern corresponding to an opening shape of the mask apertures. The method includes: as a first step, the step of aligning the substrate and the vapor deposition mask with each other using an alignment mechanism; as a second step, the step of fixing together the substrate and the vapor deposition mask aligned with each other and maintaining the substrate and the vapor deposition mask fixed together; as a third step, the step of, in a vapor deposition unit including a vapor deposition source having at least one vapor deposition source aperture and a restriction plate unit located closer to the substrate than the at least one vapor deposition source aperture, emitting vapor deposition particles from the at least one vapor deposition source aperture and then restricting emission angles of the vapor deposition particles emitted from the at least one vapor deposition source aperture by restriction apertures provided in the restriction plate unit such that vapor deposition particles emitted from the at least one vapor deposition source aperture and passing through one of the restriction apertures enter a corresponding one of the mask apertures and that vapor deposition particles emitted from the at least one vapor deposition source aperture and passing through another one of the restriction apertures that is adjacent to the one of the restriction apertures do not arrive at the corresponding one of the mask apertures; and, as a fourth step, the step of forming the film on the substrate using vapor deposition particles emitted from the at least one vapor deposition source aperture and passing through the mask apertures while one of the vapor deposition unit configured to emit the vapor deposition particles and a combination of the vapor deposition mask and the substrate aligned with each other is moved relative to the other in a first direction by a moving mechanism, the first direction being one of in-plane directions of the substrate. Therefore, even when vapor deposition is performed with the mask and the substrate spaced apart from and not in contact with each other, the vapor deposition particles travel substantially straight in the normal direction, so that the film formed is prevented from being broadened with respect to the mask apertures.

### Advantageous Effects of Invention

In some aspects of the present invention, the restriction plate unit restricts the directivity, in the in-plane directions of the substrate, of the vapor deposition particles directed toward the substrate to thereby restrict the emission angles of the vapor deposition particles such that the vapor deposition particles are directed substantially in the direction normal to the substrate. This can provide such an effect that regions of the substrate to which vapor deposition particles adhere substantially coincide with the mask apertures.

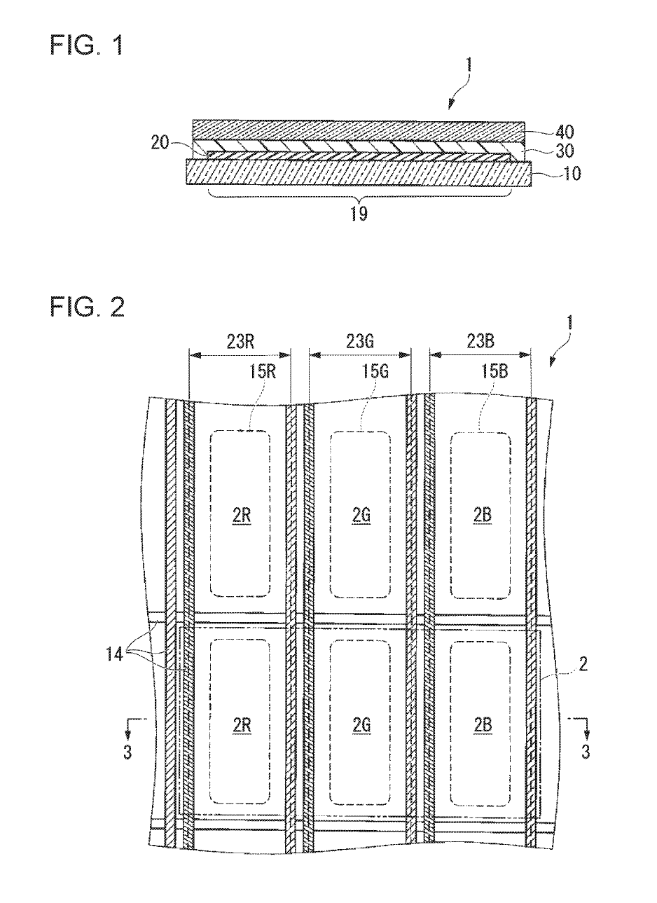

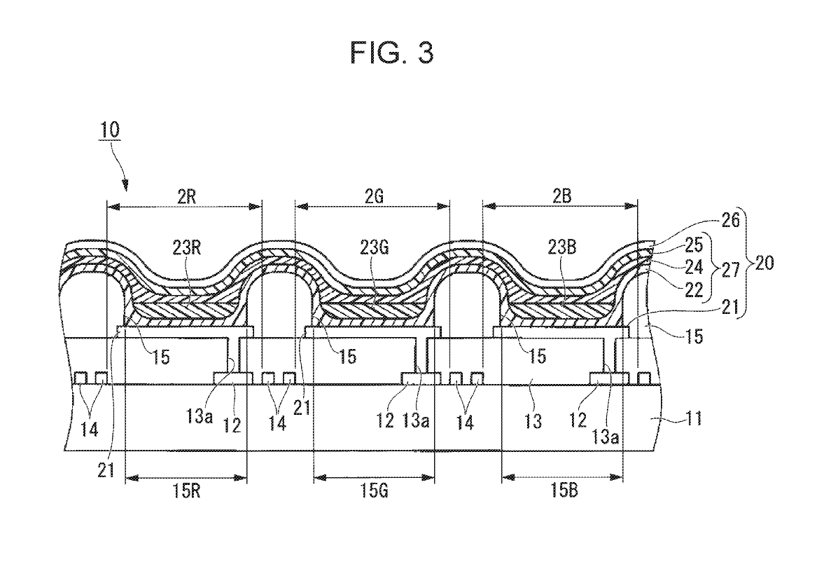

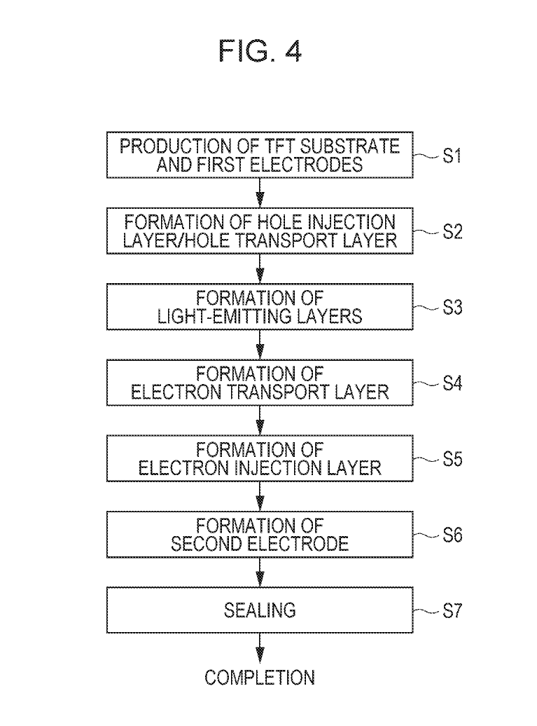

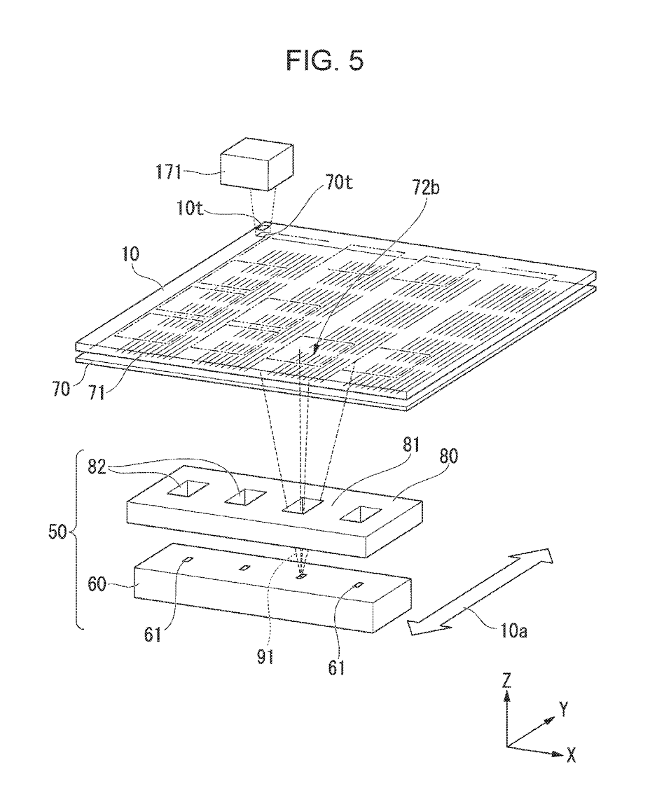

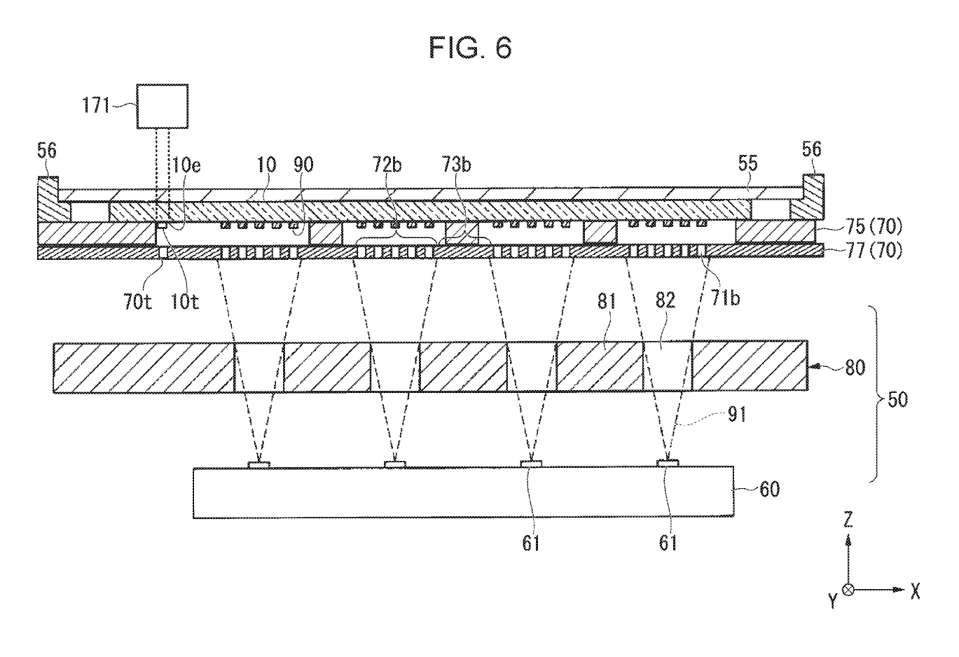

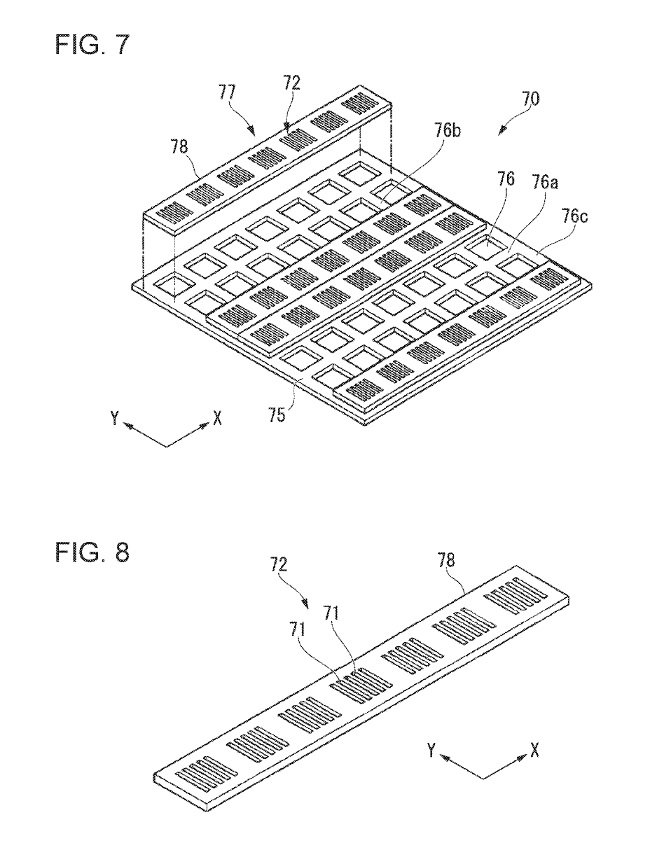

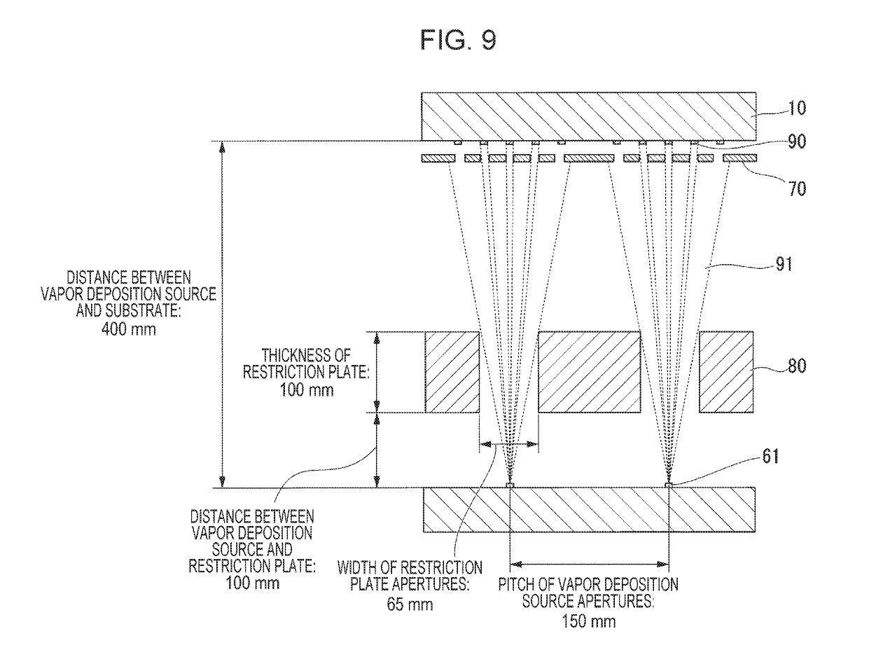

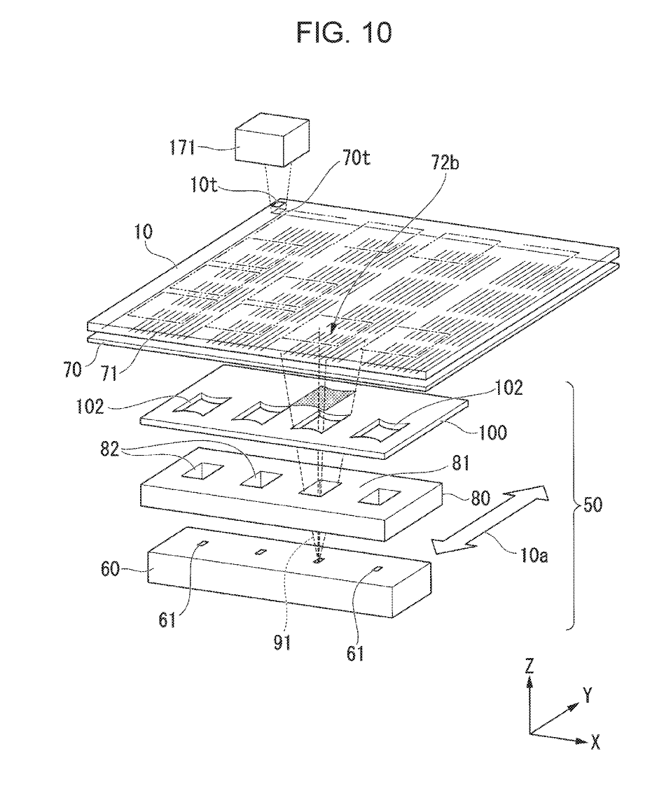

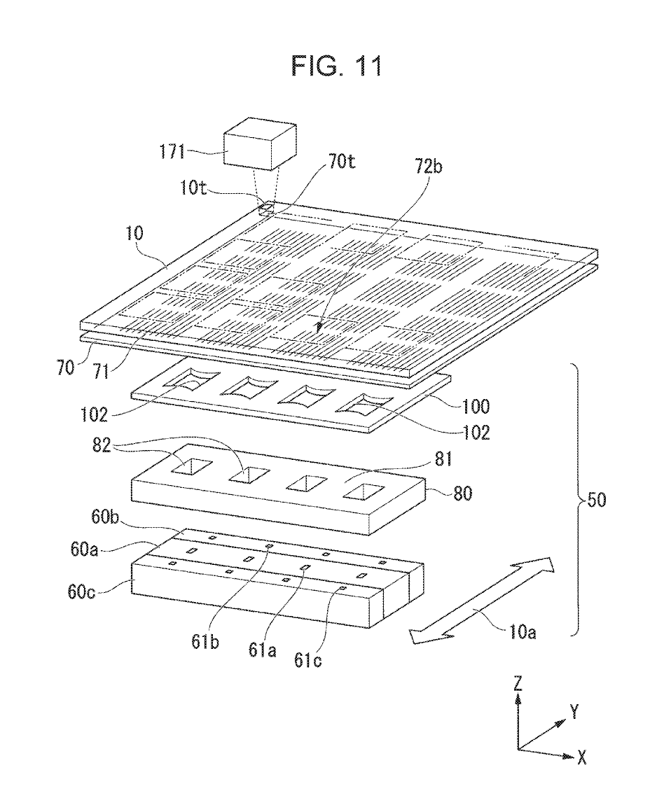

### BRIEF DESCRIPTION OF DRAWINGS

[FIG. 1] FIG. 1 is a cross-sectional view showing a schematic configuration of an organic EL display device.

[FIG. 2] FIG. 2 is a plan view showing the configuration of pixels included in the organic EL display device shown in FIG. 1.

[FIG. 3] FIG. 3 is a cross-sectional view of a TFT substrate included in the organic EL display device, the cross-sectional view being taken along arrows 3-3 in FIG. 2.

[FIG. 4] FIG. 4 is a flowchart showing the order of the steps of a process for manufacturing the organic EL display device.

[FIG. 5] FIG. 5 is a perspective view showing the basic configuration of a vapor deposition apparatus according to a first embodiment of the present invention.

[FIG. 6] FIG. 6 is a front cross-sectional view of the vapor deposition apparatus shown in FIG. 5, the front cross-sectional view being taken along a plane perpendicular to the traveling direction of a substrate and passing through vapor deposition source apertures.

[FIG. 7] FIG. 7 is an exploded perspective view of a mask included in the vapor deposition apparatus shown in FIG. 5.

[FIG. 8] FIG. 8 is a perspective view of a unit pattern mask included in the mask shown in FIG. 7.

[FIG. 9] FIG. 9 is a cross-sectional view showing how a film is formed on a substrate in the vapor deposition apparatus according to the embodiment of the present invention, the cross-sectional view being taken along a plane perpendicular to the moving direction of the substrate.

[FIG. 10] FIG. 10 is a perspective view showing the basic configuration of a vapor deposition apparatus according to a second embodiment of the present invention.

[FIG. 11] FIG. 11 is a perspective view showing the basic configuration of a vapor deposition apparatus according to a third embodiment of the present invention.

### DESCRIPTION OF EMBODIMENTS

The vapor deposition apparatus of the embodiment of the invention is a vapor deposition apparatus for forming, on a substrate, a film through a vapor deposition mask having mask apertures formed therein, the film being formed into a pattern corresponding to the opening shape of the mask apertures. The vapor deposition apparatus includes: a vapor deposition unit including a vapor deposition source having at least one vapor deposition source aperture and a restriction plate unit having formed therein restriction apertures through which vapor deposition particles emitted from the vapor deposition source aperture pass; an alignment mechanism configured to align the substrate with the mask; and a moving mechanism configured to move one of the vapor deposition unit and a combination of the substrate and the mask aligned with each other relative to the other in a first direction that is one of the in-plane directions of the substrate. The restriction apertures are disposed at positions on a side in the direction normal to the substrate with respect to the vapor deposition source aperture and are perpendicular to the substrate. The restriction plate unit restricts the directivity, in the in-plane directions, of the vapor deposition particles directed toward the substrate. Specifically, the restriction plate unit restricts the entry angles of vapor deposition particles passing through the restriction apertures such that vapor deposition particles passing through one of the restriction apertures enter a corresponding one of the mask apertures and that vapor deposition particles passing through another one of the restriction apertures that is adjacent to the one of the restriction apertures do not arrive at the corresponding one of the mask apertures. Therefore, even when vapor deposition is performed with the mask and the substrate spaced apart from and not in contact with each other, the vapor deposition particles travel substantially straight in the normal direction, so that the film formed is prevented from being broadened with respect to the mask apertures.

The phrase “travel substantially straight” means that vapor deposition particles passing through one of the restriction apertures and vapor deposition particles passing through an adjacent one of the restriction apertures pass through their respective mask apertures without being mixed with each other. However, in practice, the entry angles of vapor deposition particles are not limited to 0°.

Preferably, in the above vapor deposition apparatus of the embodiment of the invention, the mask includes an open mask having apertures and a pattern mask having end portions fixed to the open mask such that tensile force is applied to the open mask, and, during vapor deposition, the pattern mask can be spaced apart from a surface of the substrate by a distance set according to the thickness of the open mask.

In this case, a film can be formed with the mask and the substrate not in contact with each other during vapor deposition processing. Therefore, a reduction in precision due to misalignment caused by contact between the mask and the substrate can be avoided, and a reduction in precision due to the occurrence of damage to the high-definition mask caused by repeated contact and separation during the vapor deposition processing performed a plurality of times can be avoided. In addition, the adverse effect on the light-emitting characteristics due to the occurrence of damage to the surface of the deposited film caused by the contact between the film surface and the mask can be avoided. Moreover, since the vapor deposition particles travel straight, the vapor deposition beams are improved in directivity. In this case, the vapor deposition pattern is prevented from being broadened, so that a reduction in precision can be avoided.

When the vapor deposition mask is provided, it is preferable that the moving mechanism moves one of the substrate and the vapor deposition unit relative to the other in the first direction with the substrate and the vapor deposition mask spaced apart from each other by a constant spacing. In this case, the first direction dimension of the vapor deposition mask can be smaller than the first direction dimension of the substrate. This can suppress the deflection of the vapor deposition mask by its own weight and its elongation, so that vapor deposition can be easily performed on a large substrate.

In the above vapor deposition apparatus of the embodiment of the invention, the at least one vapor deposition source aperture of the vapor deposition source may include a plurality of vapor deposition source apertures, and the plurality of restriction apertures of the restriction plate unit may correspond to the plurality of vapor deposition source apertures, respectively. In this case, vapor deposition particles emitted from the vapor deposition source apertures pass through their respective restriction apertures of the restriction plate unit, and the vapor deposition particles are selectively trapped by the restriction apertures according to their entry angles, so that only vapor deposition particles having entry angles equal to or less than a prescribed angle enter the mask apertures. Therefore, the maximum entry angle of the vapor deposition particles arriving at the substrate becomes small. This allows blurring that occurs at the edges of the film formed on the substrate to be suppressed, and the precision can thereby be improved.

The restriction plate unit may be formed from a plate having a thickness in the direction normal to the substrate. In this case, the opening shape of the restriction apertures and their shape in the direction of the thickness are set before the restriction apertures are formed. This allows the maximum entry angle of the vapor deposition particles arriving at the substrate to be controlled. In addition, the efficiency of utilization of the material of vapor deposition particles can be improved while the occurrence of color mixing is prevented.

In the above vapor deposition apparatus of the embodiment of the invention, the restriction plate unit may include a film thickness correction plate disposed at a position closer to the substrate than the restriction plate unit, and the film thickness correction plate may have correction apertures corresponding to the restriction apertures, the correction apertures being configured to uniformize the distribution of deposited film thickness in a second direction that is one of the in-plane directions and orthogonal to the first direction. In this case, the distribution of deposited film thickness in the second direction in which the restriction plate unit is not moved can also be uniformized.

In the embodiment of the invention, the width of the correction apertures in the first direction may be set to be smaller at central portions with respect to the second direction than at opposite ends with respect to the second direction. In this case, non-uniformity of the film thickness in the left-right direction with respect to the direction of movement of the restriction plate unit can be reduced, so that the distribution of the deposited film thickness can be uniformized also in the second direction.

In the embodiment of invention, the vapor deposition unit may comprise a plurality of the vapor deposition sources arranged in the first direction. In this case, processing adapted to, for example, three-dimensional vapor deposition can be performed.

The vapor deposition method of the embodiment of the invention is a vapor deposition method including a vapor deposition step of causing vapor deposition particles to adhere to a substrate to thereby form a film having a prescribed patter. Preferably, the vapor deposition step is performed using any of the vapor deposition apparatuses described above.

Preferably, the above-described film is a light-emitting layer of an organic EL element.

The present invention will next be described in detail by way of preferred embodiments. It will be appreciated that the present invention is not limited to the following embodiments. Among the constituent members in the embodiments of the present invention, only principal members that are necessary to describe the present invention are simplified and shown in the drawings referenced in the following description, for the sake of convenience of the description. Therefore, the present invention may include any other constituent members not shown in the drawings. The dimensions of the constituent members in the drawings do not faithfully represent the actual dimensions, dimensional ratios, etc. of the members.

### (Configuration of Organic EL Display Device)

A description will be given of an example of an organic EL display device that can be manufactured using the present invention. The organic EL display device in the present example is of a bottom emission type in which light is extracted from a TFT substrate side. In this organic EL display device, light emission from each of pixels (sub-pixels) of different colors, i.e., red (R), green (G), and blue (B), is controlled to thereby display a full-color image.

First, the general configuration of the organic EL display device will be described.

FIG. 1 is a cross-sectional view showing a schematic configuration of the organic EL display device. FIG. 2 is a plan view showing the configuration of pixels included in the organic EL display device shown in FIG. 1. FIG. 3 is a cross-sectional view of a TFT substrate included in the organic EL display device, the cross-sectional view being taken along arrows 3-3 in FIG. 2.

As shown in FIG. 1, the organic EL display device 1 has a configuration in which organic EL elements 20, a bonding layer 30, and a sealing substrate 40 are disposed in this order on a TFT substrate 10 on which TFTs 12 (see FIG. 3) are disposed, and the organic EL elements 20 are connected to the TFTs 12. A central region of the organic EL display device 1 is a display region 19 for displaying an image, and the organic EL elements 20 are disposed within the display region 19.

The TFT substrate 10 on which the organic EL elements 20 are stacked is bonded to the sealing substrate 40 through the bonding layer 30, and the organic EL elements 20 are thereby sealed between the pair of substrates 10 and 40. Since the organic EL elements 20 are sealed between the TFT substrate 10 and the sealing substrate 40 as described above, entrance of oxygen and moisture from the outside into the organic EL elements 20 is prevented.

As shown in FIG. 3, the TFT substrate 10 includes, as a support substrate, a transparent insulating substrate 11 such as a glass substrate. When the organic EL display device is of a top emission type, it is unnecessary that the insulating substrate 11 be transparent.

As shown in FIG. 2, a plurality of lines 14 including a plurality of gate lines extending in a horizontal direction and a plurality of signal lines extending in a vertical direction and intersecting the gate lines are disposed on the insulating substrate 11. An unillustrated gate line drive circuit configured to drive the gate lines is connected to the gate lines, and an unillustrated signal line drive circuit configured to drive the signal lines is connected to the signal lines. On the insulating substrate 11, sub-pixels 2R, 2G, and 2B including red (R), green (G), and blue (B) organic EL elements 20 are disposed within regions surrounded by the lines 14 and arranged in a matrix form.

The sub-pixels 2R emit red light, and the sub-pixels 2G emit green light. The sub-pixels 2B emit blue light. Sub-pixels of the same color are arranged in a column direction (the vertical direction in FIG. 2), and a repeat unit including sub-pixels 2R, 2G, and 2B is repeated in a row direction (the horizontal direction in FIG. 2). The sub-pixels 2R, 2G, and 2B included in each repeat unit in the row direction form a pixel 2 (i.e., one pixel).

The sub-pixels 2R, 2G, and 2B include light-emitting layers 23R, 23G, and 23B, respectively, that emit light of their respective colors. The light-emitting layers 23R, 23G, and 23B are formed in a strip shape extending in the column direction (the vertical direction in FIG. 2).

The configuration of the TFT substrate 10 will be described.

As shown in FIG. 3, the TFT substrate 10 includes the TFTs 12 (switching elements), the lines 14, an interlayer film 13 (an interlayer insulating film, a planarization film), an edge cover 15, etc. that are disposed on the transparent insulating substrate 11 such as a glass substrate.

The TFTs 12 function as switching elements configured to control light emission from the sub-pixels 2R, 2G, and 2B, and one TFT 12 is provided for each of the sub-pixels 2R, 2G, and 2B. The TFTs 12 are connected to the lines 14.

The interlayer film 13 serves also as a planarization film and is stacked over the entire display region 19 on the insulating substrate 11 so as to cover the TFTs 12 and the lines 14.

First electrodes 21 are formed on the interlayer film 13. The first electrodes 21 are electrically connected to the TFTs 12 through contact holes 13a formed in the interlayer film 13.

The edge cover 15 is formed on the interlayer film 13 so as to cover pattern edges of the first electrodes 21. The edge cover 15 is an insulating layer for preventing a short circuit between a second electrode 26 and each of the first electrodes 21 included in the organic EL elements 20. A short circuit may occur at a pattern edge of a first electrode 21 because of a small thickness of an organic EL layer 27 or electric field concentration.

The edge cover 15 has openings 15R, 15G, and 15B for the sub-pixels 2R, 2G, and 2B. The openings 15R, 15G, and 15B of the edge cover 15 serve as light-emission regions of the sub-pixels 2R, 2G, and 2B. In other words, the sub-pixels 2R, 2G, and 2B are separated by the insulating edge cover 15. The edge cover 15 serves also as an element separation film.

The organic EL elements 20 will be described.

The organic EL elements 20 are light-emitting elements that are driven at a low DC voltage and can emit high intensity light. Each of the organic EL elements 20 includes a first electrode 21, the organic EL layer 27, and the second electrode 26 in this order.

Each of the first electrodes 21 is a layer having the function of injecting (supplying) holes into the organic EL layer 27. As described above, the first electrodes 21 are respectively connected to the TFTs 12 through the contact holes 13a.

As shown in FIG. 3, the organic EL layer 27 between the second electrode 26 and the first electrodes 21 includes a hole injection-transport layer 22, the light-emitting layers 23R, 23G, and 23B, an electron transport layer 24, and an electron injection layer 25 that are disposed in this order on the first electrodes 21.

In the present embodiment, the first electrodes 21 serve as anodes, and the second electrode 26 serves as a cathode. However, the first electrodes 21 may serve as cathodes, and the second electrode 26 may serve as an anode. In this case, the order of the layers included in the organic EL layer 27 is reversed.

The hole injection-transport layer 22 has the function of a hole injection layer and also has the function of a hole transport layer. The hole injection layer is a layer having the function of improving the efficiency of hole injection into the organic EL layer 27. The hole transport layer is a layer having the function of improving the efficiency of hole transport to the light-emitting layers 23R, 23G, and 23B. The hole injection-transport layer 22 is uniformly formed over the entire display region 19 in the TFT substrate 10 so as to cover the first electrodes 21 and the edge cover 15.

In the hole injection-transport layer 22 provided in the present embodiment, a hole injection layer and a hole transport layer are integrated together, but the present invention is not limited thereto. The hole injection layer and the hole transport layer may be formed as independent layers.

On the hole injection-transport layer 22, the light-emitting layers 23R, 23G, and 23B corresponding to the columns of the sub-pixels 2R, 2G, and 2B are formed so as to cover the openings 15R, 15G, and 15B of the edge cover 15. The light-emitting layers 23R, 23G, and 23B are layers having the function of emitting light as a result of recombination of holes injected from the first electrode 21 side and electrons injected from the second electrode 26 side. Each of the light-emitting layers 23R, 23G, and 23B contains a high-light emission efficiency material such as a low-molecular weight fluorescent dye or a metal complex.

The electron transport layer 24 is a layer having the function of improving the efficiency of electron transport from the second electrode 26 to the light-emitting layers 23R, 23G, and 23B.

The electron injection layer 25 is a layer having the function of improving the efficiency of electron injection from the second electrode 26 to the organic EL layer 27.

The electron transport layer 24 is uniformly formed over the entire display region 19 of the TFT substrate 10 and disposed on the light-emitting layers 23R, 23G, and 23B and the hole injection-transport layer 22 so as to cover the light-emitting layers 23R, 23G, and 23B and the hole injection-transport layer 22. The electron injection layer 25 is uniformly formed over the entire display region 19 of the TFT substrate 10 and disposed on the electron transport layer 24 so as to cover the electron transport layer 24.

In the present embodiment, the electron transport layer 24 and the electron injection layer 25 are provided as independent layers, but the present invention is not limited thereto. The electron transport layer 24 and the electron injection layer 25 may be integrated together and provided as a single layer (i.e., an electron transport-injection layer).

The second electrode 26 is a layer having the function of injecting electrons into the organic EL layer 27. The second electrode 26 is uniformly formed over the entire display region 19 of the TFT substrate 10 and disposed on the electron injection layer 25 so as to cover the electron injection layer 25.

Organic layers other than the light-emitting layers 23R, 23G, and 23B are not essential for the organic EL layer 27 and may be selected or omitted according to the required characteristics of the organic EL elements 20. The organic EL layer 27 may further include a carrier blocking layer as needed. For example, a hole blocking layer serving as a carrier blocking layer may be disposed between the electron transport layer 24 and the light-emitting layers 23R, 23G, and 23B. In this case, holes are prevented from reaching the electron transport layer 24, so that the light-emitting efficiency can be improved.

### (Method for Manufacturing Organic EL Display Device)

Next, a method for manufacturing the organic EL display device 1 will be described.

FIG. 4 is a flowchart showing the order of the steps of a process for manufacturing the organic EL display device 1.

As shown in FIG. 4, the method for manufacturing the organic EL display device 1 according to the present embodiment includes, for example, in the following order step S1 of producing the TFT substrate and the first electrodes, step S2 of forming the hole injection layer and the hole transport layer, step S3 of forming the light-emitting layers, step S4 of forming the electron transport layer, step S5 of forming the electron injection layer, step S6 of forming the second electrode, and sealing step S7.

These steps in FIG. 4 will next be described. However, the dimensions, materials, shapes, etc. of the constituent components described below are only examples, and the present invention is not limited thereto. In the present embodiment, the first electrodes 21 are anodes, and the second electrode 26 is a cathode. In contrast to this, the first electrodes 21 may be cathodes, and the second electrode 26 may be an anode. In this case, the stacking order in the organic EL layer is reversed from the order described below. Similarly, the material of the first electrodes 21 and the material of the second electrode 26 are exchanged with those described below.

First, the TFTs 12, the lines 14, etc. are formed on the insulating substrate 11 using any known method. The insulating substrate 11 used may be, for example, a transparent glass substrate or a transparent plastic substrate. One example of the insulating substrate 11 used is a rectangular glass plate with a thickness of about 1 mm and length and width dimensions of 500×400 mm.

Next, a photosensitive resin is applied to the insulating substrate 11 so as to cover the TFTs 12 and the lines 14 and is then patterned by photolithography to form the interlayer film 13. An insulating material such as an acrylic resin or a polyimide resin may be used as the material of the interlayer film 13. Generally, the polyimide resin is not transparent and has a color. Therefore, when the organic EL display device 1 of the bottom emission type as shown in FIG. 3 is manufactured, it is preferable to use a transparent resin such as an acrylic resin for the interlayer film 13. No particular limitation is imposed on the thickness of the interlayer film 13, so long as steps on the upper surfaces of the TFTs 12 can be eliminated. In one Example, an acrylic resin may be used to form an interlayer film 13 with a thickness of about 2 μm.

Next, the contact holes 13a for electrically connecting the first electrodes 21 to the TFTs 12 are formed in the interlayer film 13.

Next, the first electrodes 21 are formed on the interlayer film 13. Specifically, a conductive film (electrode film) is deposit on the interlayer film 13. Then a photoresist is applied to the conductive film and patterned by photolithography, and the conductive film is etched with ferric chloride used as an etchant. Then the photoresist is removed using a resist remover, and the substrate is washed. The first electrodes 21 in a matrix form are thereby obtained on the interlayer film 13.

The material of the conductive film used for the first electrodes 21 may be a transparent conductive material such as ITO (Indium Tin Oxide), IZO (Indium Zinc Oxide), or gallium-doped zinc oxide (GZO) or a metallic material such as gold (Au), nickel (Ni), or platinum (Pt).

The method used to deposit the conductive film may be a sputtering method, a vacuum deposition method, a CVD (chemical vapor deposition) method, a plasma CVD method, a printing method, etc. For example, ITO may be used to form first electrodes 21 with a thickness of about 100 nm by a sputtering method.

Next, an edge cover 15 having a prescribed pattern is formed. For example, the same insulating material as that of the interlayer film 13 may be used for the edge cover 15, and the edge cover 15 may be patterned using the same method as that for the interlayer film 13. In one Example, an acrylic resin may be used to form an edge cover 15 with a thickness of about 1 μm.

The TFT substrate 10 and the first electrodes 21 are produced as described above (step S1).

Next, the TFT substrate 10 produced in step S1 is subjected to baking treatment under reduced pressure for dewatering and then to oxygen plasma treatment for cleaning the surface of the first electrodes 21.

Next, a hole injection layer and a hole transport layer (the hole injection-transport layer 22 in the present embodiment) are formed on the TFT substrate 10 over the entire display region 19 of the TFT substrate 10 by a vapor deposition method (S2).

Specifically, an open mask having an aperture extending over the entire display region 19 is brought into contact with and fixed to the TFT substrate 10, and the material of the hole injection layer and the material of the hole transport layer are vapor-deposited on the entire display region 19 of the TFT substrate 10 through the aperture of the open mask while the TFT substrate 10 and the open mask are rotated together.

As described above, the hole injection layer and the hole transport layer may be integrated together or may be independent layers. The thickness of each layer is, for example, 10 to 100 nm.

Examples of the materials of the hole injection layer and the hole transport layer include benzine, styrylamine, triphenylamine, porphyrin, triazole, imidazole, oxadiazole, polyarylalkanes, phenylenediamine, arylamine, oxazole, anthracene, fluorenone, hydrazone, stilbene, triphenylene, azatriphenylene, derivatives thereof, polysilane-based compounds, and heterocyclic and chain conjugated monomers, oligomers, and polymers such as vinylcarbazole-based compounds, thiophene-based compounds, and aniline-based compounds.

In one Example, 4,4′-bis[N-(1-naphthyl)-N-phenylamino]biphenyl (α-NPD) may be used to form a hole injection-transport layer 22 with a thickness of 30 nm.

Next, light-emitting layers 23R, 23G, and 23B having a strip shape are formed on the hole injection-transport layer 22 so as to cover the openings 15R, 15G, and 15B of the edge cover 15 (S3).

The light-emitting layers 23R, 23G, and 23B are vapor-deposited such that red, green, and blue color patterns are formed in their respective prescribed regions (color-patterned vapor deposition).

Materials having high light-emitting efficiency such as low-molecular weight fluorescent dyes and metal complexes are used as the materials of the light-emitting layers 23R, 23G, and 23B. Examples of such materials include anthracene, naphthalene, indene, phenanthrene, pyrene, naphthacene, triphenylene, anthracene, perylene, picene, fluoranthene, acephenanthrylene, pentaphene, pentacene, coronene, butadiene, coumarin, acridine, stilbene, derivatives thereof, tris(8-quinolinolato)aluminum complex, bis(benzoquinolinolato)beryllium complex, tri(dibenzoylmethyl)phenanthroline europium complex, and ditoluylvinylbiphenyl.

Each of the light-emitting layers 23R, 23G, and 23B may be formed only of any of the above-described organic light-emitting materials or may contain a hole transport layer material, an electron transport layer material, additives (such as a donor and an acceptor), a light-emitting dopant, etc. Each of the light-emitting layers 23R, 23G, and 23B may have a structure in which these materials are dispersed in a macromolecular material (a binder resin) or an inorganic material. From the viewpoint of improvement in light-emitting efficiency and extension of service life, it is preferable that a light-emitting dopant is dispersed in a host.

No particular limitation is imposed on the light-emitting dopant, and any known dopant material may be used. Examples of the light-emitting dopant include aromatic dimethylidene derivatives such as 4,4′-bis(2,2′-diphenylvinyl)-biphenyl (DPVBi) and 4,4′-bis[2-{4-(N,N-diphenylamino)phenyl}vinyl]biphenyl (DPAVBi), styryl derivatives, perylene, iridium complexes, coumarin derivatives such as coumarin 6, Lumogen F Red, dicyanomethylenepyran, phenoxazone, and polyphyllin derivatives. By appropriately selecting the type of dopant, the red light-emitting layer 23R emitting red light, the green light-emitting layer 23G emitting green light, and the blue light-emitting layer 23B emitting blue light are obtained.

Examples of the host material used as the dispersion medium for the light-emitting dopant include the same materials as the materials for forming the light-emitting layers 23R, 23G, and 23B and carbazole derivatives.

No particular limitation is imposed on the amount of the dopant with respect to the host when a light-emitting layer in which the dopant is dispersed in the host is formed, and the amount may be appropriately changed according to the materials used. Generally, the amount of the dopant is preferably several percent to 30 percent.

The thickness of each of the light-emitting layers 23R, 23G, and 23B may be, for example, 10 to 100 nm.

The vapor deposition method and apparatus of the embodiment of the invention can be particularly preferably used for color-patterned vapor deposition of the light-emitting layers 23R, 23G, and 23B. The details of the method for forming the light-emitting layers 23R, 23G, and 23B using the embodiment of the invention will be described later.

Next, the electron transport layer 24 is formed over the entire display region 19 of the TFT substrate 10 by a vapor deposition method so as to cover the hole injection-transport layer 22 and the light-emitting layers 23R, 23G, and 23B (S4). The electron transport layer 24 may be formed using the same method as that in the above-described step S2 of forming the hole injection layer and the hole transport layer.

Next, the electron injection layer 25 is formed over the entire display region 19 of the TFT substrate 10 by a vapor deposition method so as to cover the electron transport layer 24 (S5). The electron injection layer 25 may be formed by the same method as that in the above-described step S2 of forming the hole injection layer and the hole transport layer.

For example, quinoline, perylene, phenanthroline, bisstyryl, pyrazine, triazole, oxazole, oxadiazole, fluorenone, derivatives thereof, metal complexes thereof, LiF (lithium fluoride), etc. may be used as the materials of the electron transport layer 24 and the electron injection layer 25.

As described above, the electron transport layer 24 and the electron injection layer 25 may be integrated together and formed as a single layer or may be formed as independent layers. The thickness of each layer is, for example, 1 to 100 nm. The total thickness of the electron transport layer 24 and the electron injection layer 25 is, for example, 20 to 200 nm.

In one Example, Alq (tris(8-hydroxyquinoline)aluminum may be used to form an electron transport layer 24 with a thickness of 30 nm, and LiF (lithium fluoride) may be used to form an electron injection layer 25 with a thickness of 1 nm.

Next, the second electrode 26 is formed over the entire display region 19 of the TFT substrate 10 by a vapor deposition method so as to cover the electron injection layer 25 (S6). The second electrode 26 may be formed by the same method as that in the above-described step S2 of forming the hole injection layer and the hole transport layer. For example, a metal having a small work function is used as the material of the second electrode 26 (electrode material). Examples such as electrode material include magnesium alloys (such as MgAg), aluminum alloys (such as AlLi, AlCa, and AlMg), and metallic calcium. The thickness of the second electrode 26 is, for example, 50 to 100 nm. In one Example, aluminum may be used to from a second electrode 26 with a thickness of 50 nm.

A protective film may be further disposed on the second electrode 26 so as to cover the second electrode 26 in order to prevent entrance of oxygen and moisture from the outside into the organic EL elements 20. An insulating or conductive material may be used as the material of the protective film, and examples of such a material include silicon nitride and silicon oxide. The thickness of the protective film is, for example, 100 to 1,000 nm.

The organic EL elements 20 each including a first electrodes 21, the organic EL layer 27, and the second electrode 26 can be formed on the TFT substrate 10 in the manner described above.

Next, as shown in FIG. 1, the TFT substrate 10 on which the organic EL elements 20 are formed and the sealing substrate 40 are bonded together through the bonding layer 30 to thereby seal the organic EL elements 20. The sealing substrate 40 used may be, for example, an insulating substrate such as a glass or plastic substrate having a thickness of 0.4 to 1.1 mm. The organic EL display device 1 is thereby obtained.

In the above organic EL display device 1, when the TFTs 12 are turned on in response to signal inputs from the lines 14, holes are injected from the first electrodes 21 to the organic EL layer 27. At the same time, electrons are injected from the second electrode 26 to the organic EL layer 27. The holes and the electrons are recombined in each of the light-emitting layers 23R, 23G, and 23B. In this case, energy is released, and light of a prescribed color is emitted. By controlling the light emission brightness of each of the sub-pixels 2R, 2G, and 2B, a prescribed image can be displayed on the display region 19.

A description will be given of step S3 of forming the light-emitting layers 23R, 23G, and 23B by color-patterned vapor deposition.

### EMBODIMENT 1

FIG. 5 is a perspective view showing the basic configuration of a vapor deposition apparatus according to a first embodiment of the present invention. FIG. 6 is a front cross-sectional view of the vapor deposition apparatus shown in FIG. 5, the front cross-sectional view being taken along a plane passing through a first vapor deposition source 60.

The vapor deposition source 60 and a restriction plate unit 80 disposed between the vapor deposition source 60 and a substrate 10 form a vapor deposition unit 50. The substrate 10 and a vapor deposition mask 70 move relative to the restriction plate unit 80 on the opposite side of the restriction plate unit 80 from the vapor deposition source 60 at a constant velocity along an arrow 10a. For the sake of convenience of description, an XYZ coordinate system is set in which a horizontal axis parallel to the moving direction 10a of the substrate 10 (a first direction) is defined as the Y axis, a horizontal axis perpendicular to the Y axis is defined as the X axis, and a vertical axis perpendicular to the X axis and the Y axis is defined as the Z axis. The Z axis is parallel to the direction normal to a deposition surface 10e of the substrate 10. For the sake of convenience of description, the side indicated by an arrow representing the Z axis direction (the upper side in the drawing sheets of FIGS. 6 and 7) is referred to as an “upper side.”

The vapor deposition source 60 includes a plurality of vapor deposition source apertures 61 on its upper surface (the surface facing the vapor deposition mask 70). The plurality of vapor deposition source apertures 61 are disposed at different positions in the X axis direction and are arranged at a constant pitch along a straight-line parallel to the X axis direction. Each of the vapor deposition source apertures 61 has a nozzle shape extending parallel to the Z axis and having an upward opening. The vapor of the material of a light-emitting layer (i.e., vapor deposition particles 91) is emitted from each of the vapor deposition source apertures 61 toward the vapor deposition mask 70. For example, the vapor of the host or dopant (vapor deposition particles 91) included in the light-emitting layer (film) 90 can be emitted from the vapor deposition source apertures 61 of the vapor deposition source 60.

The restriction plate unit 80 is disposed above the vapor deposition source 60. A plurality of restriction apertures 82 are formed in the restriction plate unit 80, and each of the restriction apertures 82 is a through hole passing through the restriction plate unit 80 in the Z axis direction. The opening shape of each of the restriction apertures 82 is a substantially rectangular shape with its major axis directions extending along the X axis and the Y axis. The plurality of restriction apertures 82 are arranged in a direction parallel to the X axis direction at the same pitch as the pitch of the plurality of vapor deposition source apertures 61. The plurality of restriction apertures 82 correspond one-to-one with the plurality of vapor deposition source apertures 61 and are disposed above their corresponding vapor deposition source apertures 61. Restriction apertures 82 adjacent to each other in the X axis direction are separated by a restriction portion 81.

The restriction plate unit 80 may include a cooling unit for cooling the restriction plate unit 80 in order to, for example, prevent re-evaporation of the vapor deposition material adhering to the restriction plate unit 80. No particular limitation is imposed on the cooling unit, and any cooling unit such as tubing through which a coolant (e.g., water) passes or a cooling element such as a Peltier element may be selected. By cooling the restriction plate unit 80, radiant heat emitted from the vapor deposition source 60 can be prevented, so that an increase in temperature of the substrate 10 and an increase in temperature of the vapor deposition mask 70 can be prevented. Therefore, thermal expansion can be prevented, and high precision can be maintained. In addition, the above effect allows the relative distance between the vapor deposition source 60 and the substrate 10 to be reduced, so that the rate of film deposition can be improved.

The vapor deposition material adheres to the restriction plate unit 80. It is therefore preferable that the restriction plate unit 80 with the vapor deposition material adhering thereto is replaced with a new restriction plate unit 80 after every predetermined period. To facilitate the replacement operation of the restriction plate unit 80, the restriction plate unit 80 may be separable into a plurality of parts.

In the present embodiment, the restriction plate unit 80 can have any shape so long as it can control vapor deposition flows 91. Desirably, the restriction plate unit 80 has a block shape shown in FIGS. 5 and 6 because the restriction plate unit 80 can be reduced in size. Similarly, in the example shown, the restriction apertures 82 have a rectangular shape but may have a tapered shape or a combination of other shapes.

The vapor deposition mask 70 is a plate-shaped member having a principal surface (a surface having the largest area) parallel to the XY plane, and a plurality of mask apertures 71 arranged in the X axis direction are formed at different positions in the X axis direction. The mask apertures 71 are thorough holes passing through the vapor deposition mask 70 in the Z axis direction. In the present embodiment, as shown in FIG. 8, the opening shape of the mask apertures 71 is a slot shape parallel to the Y axis, but the present invention is not limited thereto. Generally, it is preferable to form the vapor deposition mask 70 using, for example, invar having a small thermal expansion coefficient, and the thickness of the vapor deposition mask 70 may be generally several tens to several hundreds of micrometers. In the example shown, the mask apertures 71 have a rectangular shape but may have a tapered shape. The material of the vapor deposition mask 70 is not limited to invar. The vapor deposition mask 70 may be formed from an organic material such as polyimide, an oxide such as Al₂O₃, or a ceramic, and a combination of these material may also be used.

Preferably, the vapor deposition mask 70 is held by an unillustrated mask extension mechanism. The mask extension mechanism applies tension to the vapor deposition mask 70 in a direction parallel to its principal surface to thereby prevent the occurrence of warpage and elongation of the vapor deposition mask 70 by its own weight.

The separation distance between the substrate 10 and the vapor deposition mask 70 is 1 mm or less and desirably 300 μm or less. A large separation distance is not preferable because the broadening of a vapor-deposited pattern (film) 90 becomes large and this causes a reduction in precision. The separation distance between the substrate 10 and the vapor deposition mask 70 is desirably 5 μm or more. When the separation distance is small, the substrate 10 and the vapor deposition mask 70 are excessively close to each other. This is also not preferable because it is feared that the substrate 10 and the vapor deposition mask 70 will come into contact with each other and because very high-precision apparatus control is required.

Desirably, the separation distance between the vapor deposition mask 70 and the substrate 10 is detected by a length measuring machine such as a laser sensor and controlled using an appropriate mechanism.

Alternatively, the vapor deposition mask 70 may be an assembly including an open mask 75 and a pattern mask 77. In this configuration, the pattern mask 77 is not in contact with the substrate 10. In this case, the separation distance between the substrate 10 and the vapor deposition mask 70 can be set without using complicated means such as sensing. As shown in FIG. 7, the open mask 75 has a plurality of apertures 76. The apertures 76 of the open mask 75 are arranged so as to correspond to unit elements to be formed in the substrate.

The open mask 75 further includes: ribs 76a that separate the plurality of apertures 76 in a column direction, i.e., in the y direction; and ribs 76b that separate the plurality of apertures 76 in a row direction, i.e., in the x direction. In the figure, numeral 76c represents an outer rib.

The pattern mask 77 includes a plurality of unit pattern masks 78. As shown in the figure, each of the unit pattern masks 78 is formed from a stripe-shaped thin plate. Each unit pattern mask 78 includes a plurality of mask pattern sections 72 arranged in the lengthwise direction of the unit pattern mask 78, i.e., in the x direction.

Each of the mask pattern sections 72 has a plurality of mask apertures 71 forming the same pattern as a pattern of organic EL light-emitting elements to be formed on the substrate. The apertures 71 of each mask pattern section 72 are formed by stripe-shaped shielding portions. The apertures 71 are parallel to each other and each have a slit shape extending in the width direction of the unit pattern masks 78, i.e., in the y direction.

In each of the unit pattern masks 78 of the pattern mask 77, a plurality of mask pattern sections 72 are arranged in the lengthwise direction (the x direction). Each unit pattern mask 78 is held at its opposite ends in the arrangement direction of the mask pattern sections 72, i.e., in the x direction, by the open mask 75.

Each unit pattern mask 78 is supported at its opposite ends such that tensile force is applied to the open mask 75. Each unit pattern mask 78 is fixed and welded to the open mask 75 such that the mask pattern sections 72 of the unit pattern mask 78 correspond to their respective apertures 76 of the open mask 75 that are arranged in the column direction.

In this case, the unit pattern masks 78 are supported by the open mask 75 in a direction orthogonal to the apertures 71 of the mask pattern sections 72, and the distance between the unit pattern masks 78 is maintained by the ribs 76a.

The pattern mask 77 is positioned so as to be separated from the substrate 10 by the thickness of the open mask 75.

In the figure, the number of vapor deposition source apertures 61 arranged in the X axis direction is 4, and the number of restriction apertures 82 arranged in the X axis direction is also 4. However, the present embodiment is not limited thereto, and the numbers of these apertures 61 and 82 may be larger than 4 and may be smaller than 4.

The plurality of vapor deposition source apertures 61 are spaced apart from the restriction plate unit 80 in the Z axis direction, and the restriction plate unit 80 is spaced apart from the vapor deposition mask 70 in the Z axis direction. The relative positions of the vapor deposition source 60 and the restriction plate unit 80 are preset and fixed in advance, and the vapor deposition source 60 and the restriction plate unit 80 move as a unit relative to the substrate 10. Preferably, the substrate 10 and the vapor deposition mask 70 are aligned with each other before vapor deposition processing, and the aligned state is maintained substantially unchanged at least during vapor deposition. Alignment means such as alignment marks 10t and 70t shown in FIGS. 5 and 6 are provided in the substrate 10 and the vapor deposition mask 70, respectively. This allows the substrate 10 and the vapor deposition mask 70 to be aligned with each other.

The substrate 10 is held by a holding device 55. The holding device 55 used may be, for example, an electrostatic chuck that holds a surface of the substrate 10 that is opposite to the deposition surface 10e by electrostatic force. In this manner, the substrate 10 can be held with substantially no deflection by its own weight. The holding device 55 for holding the substrate 10 is not limited to the electrostatic chuck, and any other device may be used.

The substrate 10 held by the holding device 55 and the vapor deposition mask 70 are moved (transferred) by a moving mechanism 56 on the opposite side of the vapor deposition unit 50 from the vapor deposition source 60 at a constant velocity in the moving direction 10a parallel to the Y axis while spaced apart from the restriction plate unit 80 by a constant spacing.

The substrate 10 and the vapor deposition mask 70 may be reciprocated or may be moved in only one direction. No particular limitation is imposed on the configuration of the moving mechanism 56. Any known transfer driving mechanism such as a liner motor or a feed screw mechanism in which a screw is rotated by a motor may be used. While the substrate 10 is moved, the alignment between the substrate 10 and the vapor deposition mask 70 is maintained.

The vapor deposition unit 50, the substrate 10, the holding device 55 that holds the substrate 10, and the moving mechanism 56 that moves the substrate 10 are contained in an unillustrated vacuum chamber. The vacuum chamber is a sealed container, and its interior space is reduced in pressure and maintained in a prescribed low-pressure state.

The vapor deposition apparatus in the present embodiment includes, in addition to the vacuum chamber, alignment observation means 171 such as an image sensor, an unillustrated control circuit, etc.

The vapor deposition particles 91 emitted from the vapor deposition source apertures 61 pass through the restriction apertures 82 of the restriction plate unit 80 and the mask apertures 71 of the vapor deposition mask 70 in this order. The vapor deposition particles 91 passing through the mask apertures 71 adhere to the deposition surface 10e of the substrate 10 (i.e., the surface of the substrate 10 that faces the vapor deposition mask 70) and thereby form a film 90. The film 90 has a planar shape corresponding to the shape of the mask apertures 71 of the vapor deposition mask 70.

As shown in FIG. 6, in the vapor deposition mask 70, a region at which the vapor deposition particles 91 passing through the restriction apertures 82 arrive is referred to as a vapor deposition region 72b. A plurality of vapor deposition regions 72b are arranged in the X axis direction at a constant pitch. Vapor deposition regions 72b adjacent in the X axis direction do not overlap each other and are independent of each other. A non-vapor deposition region 73b at which the flow of vapor deposition particles 91 (a vapor deposition flow) does not arrive is formed between adjacent vapor deposition regions 72b. The vapor deposition regions 72b have a substantially rectangular shape corresponding to the opening shape of the restriction apertures 82. The vapor deposition regions 72b are arranged along a straight-line parallel to the X axis. The mask apertures 71 are formed only within the vapor deposition regions 72b. The non-vapor deposition regions 73b extend in a direction parallel to the Y axis.

The vapor deposition particles 91 forming the film 90 always pass through the restriction apertures 82 and their corresponding mask apertures 71. The vapor deposition particles 91 pass through their corresponding restriction apertures 82 and then arrive at the deposition surface 10e of the substrate 10 and do not pass through adjacent restriction apertures 82. The restriction plate unit 80 and the vapor deposition mask 70 are designed such that the vapor deposition particles 91 emitted from the vapor deposition source apertures 61 do not arrive at the deposition surface 10e of the substrate 10 without passing through the restriction apertures 82 and the mask apertures 71. Moreover, for example, a deposition preventing plate (not shown) for disturbing the flight of the vapor deposition particles 91 may be disposed as needed.

Vapor deposition is performed three times using different materials for vapor deposition particles 91 of red, green, and blue colors (color-patterned vapor deposition), and rectangular films 90 for red, green, and blue colors (i.e., the light-emitting layers 23R, 23G, and 23B) can thereby formed on the deposition surface 10e of the substrate 10.

In the present embodiment, as shown in FIG. 6, the vapor deposition particles 91 emitted from the vapor deposition source apertures 61 have some broadening (directivity). Specifically, the number of vapor deposition particles 91 emitted from a vapor deposition source aperture 61 is largest in the upward vertical direction extending from the vapor deposition source aperture 61 (in the Z axis direction) and gradually decreases as the angle (the emission angle) with respect to the upward vertical direction increases. The vapor deposition particles 91 emitted from the vapor deposition source apertures 61 travel straight in their respective emission directions. Therefore, if there is no restriction plate unit 80, vapor deposition particles flying through a mask aperture 71 include not only vapor deposition particles emitted from a vapor deposition source aperture located directly below this mask aperture 71 but also vapor deposition particles emitted from vapor deposition source apertures located obliquely below the mask aperture 71, although the vapor deposition particles emitted from the vapor deposition source aperture located directly below the mask aperture 71 occupy the largest percentage.

When vapor deposition particles 91 flying from various directions pass through a mask aperture 71 as described above, the number of vapor deposition particles 91 arriving at the deposition surface 10e of the substrate 10 is largest in a region directly above this mask aperture 71 and gradually decreases as the distance from this region increases. Therefore, on the deposition surface 10e of the substrate 10, a thick main film portion having a substantially constant thickness is formed in a region of the substrate 10 onto which the above mask aperture 71 is projected vertically upward, and blurring portions in which their thickness gradually decreases as the distance from the main film portion increases are formed on both sides of the main film portion. These blurring portions cause blurring at edges of the film 90.

To reduce the width of the blurring portions, the spacing between the vapor deposition mask 70 and the substrate 10 is reduced. However, when the vapor deposition mask 70 is in contact with the substrate 10, a problem such as a reduction in precision occurs. Therefore, the spacing between the vapor deposition mask 70 and the substrate 10 cannot be reduced to zero.

In the present embodiment, as shown in FIG. 6, the restriction plate unit 80 integrated with the vapor deposition source 60 to form a single unit is disposed. Vapor deposition particles 91 emitted from each of the vapor deposition source apertures 61 have some broadening (directivity). Among these vapor deposition particles 91, those having a large X axis direction velocity vector component impinge on and adhere to the restriction portions 81, therefore cannot pass through the restriction apertures 82, and cannot arrive at the mask apertures 71. Specifically, the restriction portions 81 restricts the spread angles, in the X axis direction and the Y direction, of the vapor deposition flows of the vapor deposition particles 91 emitted from the vapor deposition source apertures 61. Therefore, the entry angles of the vapor deposition particles 91 entering the mask apertures 71 are restricted. The “entry angle” of a vapor deposition particle 91 in the X direction at a mask aperture 71 is defined as the angle which the flying direction of the vapor deposition particle 91 entering the mask aperture 71 makes with the Z axis in a projection onto the XZ plane.

By disposing the plurality of restriction portions 81 as described above, the directivity of the vapor deposition particles 91 in the X axis direction and the Y direction is improved. Therefore, the width of the blurring portions can be reduced, and a high-definition film 90 can be formed according to the shape of the mask apertures 71). When the vapor deposition apparatus in the present embodiment is used to perform color-patterned vapor deposition of the light-emitting layers 23R, 23G, and 23B, the occurrence of color mixing can be prevented. This allows the pitch of the pixels to be reduced. In this case, an organic EL display device capable of high-definition display can be provided. The light emitting regions may be enlarged without changing the pitch of the pixels. In this case, an organic EL display device capable of high-brightness display can be provided. Since it is unnecessary to increase current density in order to obtain high brightness, a reduction in the service life of the organic EL elements and damage to the organic EL elements are prevented, so that a reduction in reliability can be prevented.

In the present embodiment, the vapor deposition mask 70 aligned with the substrate 10 is moved relative to the vapor deposition unit 50 in the moving direction 10a, and processing is performed while the emission angles of the vapor deposition particles 91 are restricted by the restriction plate unit 80 to thereby control the direction of the vapor deposition flows 91. Therefore, even when the vapor deposition mask 70 is spaced apart from the substrate 10, a film 90 having a planar shape precisely corresponding to the mask apertures 71 can be formed. This can prevent various adverse effects that occur when the conventional high-definition mask is brought into contact with the substrate.

The vapor deposition method in the present embodiment is a vapor deposition method in which vapor deposition particles 91 are caused to adhere to the substrate 10 through the vapor deposition mask 70 having the mask apertures 71 formed therein to thereby form a film 90 having a pattern corresponding to the opening shape of the mask apertures 71. The method includes: as a first step, the step of aligning the substrate 10 and the vapor deposition mask 70 with each other using the alignment marks 10t and 70t and an image sensor 171 serving as an alignment mechanism; as a second step, the step of fixing together the substrate 10 and the vapor deposition mask 70 aligned with each other and maintaining the substrate 10 and the vapor deposition mask 70 fixed together; as a third step, the step of emitting vapor deposition particles 91 from the vapor deposition source apertures 61 of the vapor deposition source 60 and then restricting the emission angles of the vapor deposition particles 91 by the restriction apertures 82 such that vapor deposition particles emitted from one of the restriction apertures 82 and passing through one of the restriction apertures 82 formed in the restriction plate unit 80 located closer to the substrate 10 than the vapor deposition source apertures 61 enter a corresponding one of the mask apertures 71 and that vapor deposition particles emitted from another one of the restriction apertures 82 and passing through another one of the restriction apertures 82 that is adjacent to the one of the restriction apertures 82 do not arrive at the corresponding one of the mask apertures 71; and, as a fourth step, the step of forming a film 90 on the substrate 10 using the vapor deposition particles 91 passing through the mask apertures 71 while one of the vapor deposition unit 50 configured to emit the vapor deposition particles 91 and a combination of the vapor deposition mask 70 and the substrate 10 aligned with each other is moved relative to the other in the first direction (moving direction) 10a that is one of the in-plane directions of the substrate 10.

Examples of the dimensions of features of the vapor deposition apparatus in the present embodiment are shown in FIG. 9.

In the present embodiment, the vapor deposition mask 70 aligned with the substrate 10 is moved relative to the vapor deposition unit 50 in the moving direction 10a, and the processing is performed while the direction of the vapor deposition flows 91 is controlled by the restriction plate unit 80. Therefore, the restriction plate unit 80 can be set such that the vapor deposition particles arriving at the substrate 10 always fly through any one of the vapor deposition source apertures 61. By arranging the restriction apertures 82 and the vapor deposition source apertures 61 such that they correspond one-to-one with each other, the direction of the vapor deposition flows 91 can be easily controlled to be close to the Z direction.

In the present embodiment, the vapor deposition mask 70 aligned with the substrate 10 is moved relative to the vapor deposition unit 50 in the moving direction 10a, and the processing is performed while the direction of the vapor deposition flows 91 is controlled by the restriction plate unit 80. Therefore, the vapor deposition regions 72b can have a planar shape corresponding to the planer shape of the light-emitting layers 23R, 23G, and 23B to be formed on the substrate 10. With the above arrangement, a steep change in thickness of the light-emitting layers 23R, 23G, and 23B and the occurrence of discontinuity of the deposited patterns can be prevented.

In the present embodiment, the vapor deposition mask 70 aligned with the substrate 10 is moved relative to the vapor deposition unit 50 in the moving direction 10a, and the processing is performed while the direction of the vapor deposition flows 91 is controlled by the restriction plate unit 80. Therefore, the vapor deposition regions 72b corresponding to the plurality of restriction apertures 82 in the X direction can be processed simultaneously. This allows the vapor deposition processing to be performed on a large area simultaneously.

In the present embodiment, the vapor deposition mask 70 aligned with the substrate 10 is moved relative to the vapor deposition unit 50 in the moving direction 10a, and the processing is performed while the direction of the vapor deposition flows 91 is controlled by the restriction plate unit 80. The positional relation between the restriction plate unit 80 and the vapor deposition source 60 is fixed to form a single unit, and the single unit can be moved (transferred) relative to the substrate 10 and the vapor deposition mask 70. This allows film deposition on a substrate 10 having a large area, and a uniform film thickness distribution can also be obtained.

### SECOND EMBODIMENT

A second embodiment of the vapor deposition apparatus according to the present invention will be described with reference to the drawings.

FIG. 10 is a perspective view showing the vapor deposition apparatus in the present embodiment.

The present embodiment is different from the above-described first embodiment in that a film thickness correction plate is provided. Constituent members other than the film thickness correction plate are denoted by the same numerals as those in the first embodiment, and their description will be omitted.

In the vapor deposition apparatus in the present embodiment, the film thickness correction plate 100 is disposed in the uppermost portion of the vapor deposition unit 50.

As shown in FIG. 10, the arrangement state of the film thickness correction plate 100, the vapor deposition source 60, and the restriction plate unit 80 is fixed, and they are integrated together and disposed as the vapor deposition unit 50.

As shown in FIG. 10, the film thickness correction plate 100 has a plurality of correction apertures 102 corresponding to the restriction apertures 72 of the restriction plate unit 80. The correction apertures 102 are disposed at positions corresponding one-to-one with the restriction apertures 82 of the restriction plate unit 80.

The correction apertures 102 have a shape that is set such that the distribution of film thickness in the X direction is uniformized. Specifically, the dimension of the correction apertures 102 in the substrate moving direction 10a is set to be smaller at central portions with respect to the X direction (the second direction) than at opposite ends with respect to the X direction. In the vapor deposition unit 50 moving in the Y direction relative to the substrate 10 and the vapor deposition mask 70, the film thickness distribution is uniformized in the Y direction. However, since the vapor deposition unit 50 does not move in the X direction, the vapor deposition flows 91 through the mask apertures 71 are corrected in the X direction.

In the preceding embodiment, the vapor deposition particles 91 emitted from the vapor deposition source apertures 61 have some broadening (directivity). The number of vapor deposition particles 91 emitted from a vapor deposition source aperture 61 and passing through the restriction plate unit 80 is largest in the upward vertical direction extending from the vapor deposition source aperture 61 (in the Z axis direction) and gradually decreases as the angle (the emission angle) with respect to the upward vertical direction increases. The vapor deposition mask 70 aligned with the substrate 10 is moved relative to the vapor deposition unit 50 in the moving direction 10a, i.e., the Y direction, and the processing is performed while the broadening of the vapor deposition flows 91 in the X and Y directions is restricted by the restriction plate unit 80. Therefore, in the Y direction, i.e., the moving direction 10a, a vapor deposition flow having a diagonal component is cancelled as the substrate 10 moves. However, the vapor deposition mask 70 aligned with the substrate 10 does not move relative to the vapor deposition unit 50 in the X direction. Therefore, a thick main film portion having a substantially constant thickness is formed in a region of the substrate 10 onto which a mask aperture 71 is projected vertically upward, and blurring portions in which their thickness gradually decreases as the distance from the main film portion increases are formed on both sides of the main film portion. In this case, the uniformity of the film thickness in the X direction is worse than that in the Y direction.

However, as shown in FIG. 10, in the present embodiment, the film thickness correction plate 100 is provided in addition to the restriction plate unit 80 integrated with the vapor deposition source 60 to form a single unit.

The vapor deposition particles 91 emitted from the vapor deposition source apertures 61 have some broadening (directivity). Among these vapor deposition particles 91, those having a large X axis direction velocity vector component impinge on and adhere to correction portions 101 of the film thickness correction plate 100, therefore cannot pass through the correction apertures 102, and cannot arrive at the mask apertures 71. Specifically, the correction portions 101 restricts the spread angles, in the X axis direction, of the vapor deposition flows of the vapor deposition particles 91 emitted from the restriction apertures 82. Among vapor deposition particles flying through each mask aperture 71, those emitted from a vapor deposition source aperture located directly below the each mask aperture 71 occupy the largest percentage. However, near the central portion of the mask aperture 71, the number (amount) of vapor deposition particles 91 entering the mask aperture 71 is reduced according to the Y directional shape of the correction aperture 102.

The non-uniformity of the film thickness in the Y direction can be reduced by the movement of the vapor deposition unit 50 relative to the substrate 10 and the vapor deposition mask 70. In addition, the non-uniformity of the film thickness in the X direction can be reduced by the shape of the correction apertures 102 of the film thickness correction plate 100. In this manner, a film 90 having high film thickness uniformity in both the X and Y directions can be easily formed.

In the present embodiment, vapor deposition particles 91 emitted from each vapor deposition source aperture 61 have an original distribution in which the number of vapor deposition particles 91 takes a maximum value at a position directly above the vapor deposition source aperture 61 and gradually decreases toward the outer side. The non-uniformity of the distribution of the number of vapor deposition particles 91 in the moving direction 10a of the vapor deposition unit 50 is reduced by moving the vapor deposition unit 50. The non-uniformity of the distribution in the X direction, i.e., the horizontal direction, can be cancelled by introducing the film thickness correction plate 100, integrating the film thickness correction plate 100 with the vapor deposition source 60, and moving them together. This allows a very good film thickness distribution to be obtained over the entire substrate 10.

In the present embodiment, the film thickness is corrected using the film thickness correction plate 100. However, the film thickness can be corrected by changing the shape of the restriction apertures 82 of the restriction plate unit 80 according to the shape settings of the correction apertures 102 described above. To set the directions of the vapor deposition particles 91 adequately, it is necessary that the thickness of the restriction plate unit 80 be larger than the thickness of the film thickness correction plate 100. Therefore, in consideration of processing precision, the state of controlling the film thickness uniformity can be improved more easily by using the film thickness correction plate 100 as in the present embodiment.

### THIRD EMBODIMENT

A third embodiment of the vapor deposition apparatus according to the present invention will be described with reference to the drawings.

FIG. 11 is a perspective view showing the vapor deposition apparatus in the present embodiment.

The present embodiment is different from the above-described second embodiment in that the vapor deposition source can perform three-dimensional vapor deposition. Constituent members other than the vapor deposition source are denoted by the same numerals as those in the second embodiment, and their description will be omitted.

The present embodiment is suitable for the formation of a light-emitting layer containing a plurality of different types of dopants in a host. In the present embodiment, the vapor deposition source 60 includes a first vapor deposition source 60a, a second vapor deposition source 60b, and a third vapor deposition source 60c. The third vapor deposition source 60c is disposed on the opposite side of the first vapor deposition source 60a from the second vapor deposition source 60b in the Y axis direction. The first vapor deposition source 60a, the second vapor deposition source 60b, and the third vapor deposition source 60c respectively include, on their upper surfaces (on the side toward the vapor deposition mask 70), a plurality of first vapor deposition source apertures 61a, a plurality of second vapor deposition source apertures 61b, and a plurality of third vapor deposition source apertures 61c that are similar to the vapor deposition source apertures 61. The plurality of first vapor deposition source apertures 61a, the plurality of second vapor deposition source apertures 61b, and the plurality of third vapor deposition source apertures 61c are arranged at a constant pitch along a straight-line parallel to the X axis direction, as are the vapor deposition source apertures 61. Each of the plurality of first vapor deposition source apertures 61a, each of the plurality of second vapor deposition source apertures 61b, each of the plurality of third vapor deposition source apertures 61c, and their corresponding components may be disposed at the same X direction position, as is the vapor deposition source apertures 61. The vapor deposition source apertures 61a, 61b, and 61c each have a nozzle shape, as do the vapor deposition source apertures 61.

The first vapor deposition source apertures 61a emit the vapor of a first material (first vapor deposition particles 91a) used as a material of a light-emitting layer with some broadening (directivity) in the X axis direction and the Y axis direction toward the vapor deposition mask 70.

The second vapor deposition source apertures 61b emit the vapor of a second material (second vapor deposition particles 91b) used as a material of the light-emitting layer with some broadening (directivity) in the X axis direction and the Y axis direction toward the vapor deposition mask 70.

The third vapor deposition source apertures 61c emit the vapor of a third material (third vapor deposition particles 91c) used as a material of the light-emitting layer with some broadening (directivity) in the X axis direction and the Y axis direction toward the vapor deposition mask 70.

The second vapor deposition source apertures 61b are inclined such that their opening direction is directed toward the first vapor deposition source apertures 61a, and the third vapor deposition source apertures 61c are also inclined such that their opening direction is directed toward the first vapor deposition source apertures 61a.

For example, the vapor of a host (the first vapor deposition particles 91a) included in the light-emitting layer may be emitted from the first vapor deposition source apertures 61a of the first vapor deposition source 60a. The vapor of a first dopant (the second vapor deposition particles 91b) included in the light-emitting layer may be emitted from the second vapor deposition source apertures 61b of the second vapor deposition source 60b, and the vapor of a second dopant (the third vapor deposition particles 91c) included in the light-emitting layer may be emitted from the third vapor deposition source apertures 61c of the third vapor deposition source 60c. The first dopant and the second dopant are different materials.

In the present embodiment, the shape settings of the restriction apertures 82 of the restriction plate unit 80 are set so as to support three-dimensional vapor deposition.

Specifically, for example, each of the restriction apertures 82 may include three independent apertures for the three vapor deposition source apertures, and this depends on the size and arrangement of the constituent members.

The restriction plate unit 80 restricts the directivity of the first, second, and third vapor deposition particles 91a, 91b, and 91c in the Y axis direction such that the spread angles (divergence angles) of the flows of the first, second, and third vapor deposition particles 91a, 91b, and 91c directed toward the substrate 10 are θa, θb, θc in a projection on the YZ plane. Let regions on the substrate 10 to which the first, second, and third vapor deposition particles 91a, 91b, and 91c adhere if the vapor deposition mask 70 is not disposed be first, second, and third regions 92a, 92b, and 92c. Then the Y axis direction positions of the first, second, and third regions 92a, 92b, and 92c substantially coincide with each other when viewed in the X axis direction. In other words, the components of the restriction plate unit 80 are configured such that the first region 92a, the second region 92b, and the third region 92c substantially coincide with each other. Also, the position of the restriction plate unit 80 relative to the positions of the first, second, and third vapor deposition source apertures 61a, 61b, and 61c and the substrate 10 are set such that the first region 92a, the second region 92b, and the third region 92c substantially coincide with each other.

However, for particular sizes and arrangement of the constituent members, it may be difficult to allow the positions of the 91a, 91b, and 91c to coincide with each other. In such a case, the regions are further corrected by the film thickness correction plate 100, and the corrected regions are referred to as 91d, 91e, and 91f. The film thickness correction plate 100 is configured such that the regions 91d, 91e, 91f substantially coincide with each other.

Also in the present embodiment, by adjusting the position of the restriction plate unit 80, the shape of the restriction apertures 82, the position of the film thickness correction plate 100, and the shape of the correction apertures 102, the directions of the vapor deposition flows 91a, 91b, and 91c flying from the three vapor deposition sources apertures 61a, 61b, and 61c can be controlled simultaneously, and the three thicknesses can be corrected simultaneously.

In the above embodiments, the substrate 10 and the vapor deposition mask 70 are moved relative to the fixed vapor deposition unit 50, but the present invention is not limited thereto. One of the vapor deposition unit 50 and a combination of the substrate 10 and the vapor deposition mask 70 may be moved relative to each other. For example, the positions of the substrate 10 and the vapor deposition mask 70 are fixed, and the vapor deposition unit 50 may be moved. Alternatively, both the vapor deposition unit 50 and the combination of the substrate 10 and the vapor deposition mask 70 may be moved.

In the examples described in the above embodiments, the light-emitting layers of the organic EL elements are formed. However, the present invention can also be used when various thin films other than the light-emitting layers of the organic EL elements are formed by a vapor deposition method.

### INDUSTRIAL APPLICABILITY

No particular limitation is imposed on the application fields of the vapor deposition apparatus and method of the present invention. However, the vapor deposition apparatus and method can be preferably used to form light-emitting layers of organic EL display devices.

### REFERENCE SIGNS LIST

10 substrate
10a first direction
10t alignment mark (alignment mechanism)
20 organic EL element
23R, 23G, 23B light-emitting layer
50 vapor deposition unit
56 moving mechanism
60 vapor deposition source
61 vapor deposition source aperture
70 vapor deposition mask
70t alignment mark (alignment mechanism)
71 mask aperture
72b vapor deposition region
80 restriction plate unit
82 restriction aperture
90 film
91 vapor deposition particles
100 film thickness correction plate
102 correction aperture
171 alignment observation means (alignment mechanism)

1. A vapor deposition apparatus for forming, on a substrate, a film through a vapor deposition mask having mask apertures formed therein, the film being formed into a pattern corresponding to an opening shape of the mask apertures,
the vapor deposition apparatus comprising:
a vapor deposition unit including a vapor deposition source having at least one vapor deposition source aperture and a restriction plate unit having formed therein a plurality of restriction apertures through which vapor deposition particles emitted from the at least one vapor deposition source aperture pass;
an alignment mechanism configured to align the substrate with the vapor deposition mask; and
a moving mechanism configured to move one of the vapor deposition unit and a combination of the substrate and the vapor deposition mask aligned with each other relative to the other in a first direction, the first direction being one of in-plane directions of the substrate,
wherein the restriction apertures are disposed at positions on a side in a direction normal to the substrate with respect to the at least one vapor deposition source aperture and are perpendicular to the substrate,
the restriction plate unit restricts entry angles of vapor deposition particles emitted from the at least one vapor deposition source aperture and passing through the restriction apertures such that vapor deposition particles emitted from the at least one vapor deposition source aperture and passing through one of the restriction apertures enter a corresponding one of the mask apertures and that vapor deposition particles emitted from the at least one vapor deposition source aperture and passing through another one of the restriction apertures that is adjacent to the one of the restriction apertures do not arrive at the corresponding one of the mask apertures,
a aligned state of the substrate and the vapor deposition mask is fixed before vapor deposition processing, and
the aligned state is maintained unchanged at least during vapor deposition.

2. The vapor deposition apparatus according to claim 1, wherein the vapor deposition mask includes:
an open mask having apertures; and
a pattern mask having end portions fixed to the open mask such that tensile force is applied to the open mask, and,
wherein, during vapor deposition, the pattern mask can be spaced apart from a surface of the substrate by a distance set according to the thickness of the open mask.

3. The vapor deposition apparatus according to claim 1, wherein
the at least one vapor deposition source aperture of the vapor deposition source comprises a plurality of vapor deposition source apertures, and the plurality of restriction apertures of the restriction plate unit correspond to the plurality of vapor deposition source apertures, respectively.

4. The vapor deposition apparatus according to claim 1, wherein the restriction plate unit is formed from a plate having a thickness in the direction normal to the substrate.

5. The vapor deposition apparatus according to claim 1, wherein the restriction plate unit includes a film thickness correction plate disposed at a position closer to the substrate than the restriction plate unit, and the film thickness correction plate has correction apertures corresponding one-to-one with the restriction apertures, the correction apertures being configured to uniformize the distribution of deposited film thickness in a second direction, the second direction being one of the in-plane directions and orthogonal to the first direction.

6. The vapor deposition apparatus according to claim 5, wherein the width of the correction apertures in the first direction is set to be smaller at central portions with respect to the second direction than at opposite ends with respect to the second direction.

7. The vapor deposition apparatus according to claim 1, wherein the vapor deposition unit comprises a plurality of the vapor deposition sources arranged in the first direction.

8. A vapor deposition method in which vapor deposition particles are caused to adhere to a substrate through a vapor deposition mask having mask apertures formed therein to thereby form a film having a pattern corresponding to an opening shape of the mask apertures,
the method comprising:
as a first step, the step of aligning the substrate and the vapor deposition mask with each other using an alignment mechanism;
as a second step, the step of fixing together the substrate and the vapor deposition mask aligned with each other and maintaining the substrate and the vapor deposition mask fixed together;
as a third step, the step of, in a vapor deposition unit including a vapor deposition source having at least one vapor deposition source aperture and a restriction plate unit located closer to the substrate than the at least one vapor deposition source aperture, emitting vapor deposition particles from the at least one vapor deposition source aperture and then restricting emission angles of the vapor deposition particles emitted from the at least one vapor deposition source aperture by restriction apertures provided in the restriction plate unit such that vapor deposition particles emitted from the at least one vapor deposition source aperture and passing through one of the restriction apertures enter a corresponding one of the mask apertures and that vapor deposition particles emitted from the at least one vapor deposition source aperture and passing through another one of the restriction apertures that is adjacent to the one of the restriction apertures do not arrive at the corresponding one of the mask apertures; and
as a fourth step, the step of forming the film on the substrate using vapor deposition particles emitted from the at least one vapor deposition source aperture and passing through the mask apertures while one of the vapor deposition unit configured to emit the vapor deposition particles and a combination of the vapor deposition mask and the substrate aligned with each other is moved relative to the other in a first direction by a moving mechanism, the first direction being one of in-plane directions of the substrate, and
wherein an aligned state of the substrate and the vapor deposition mask is maintained unchanged at least during vapor deposition.

9. The vapor deposition method according to claim 8, wherein the film is a light-emitting layer of an organic EL element.

10. The vapor deposition apparatus according to claim 7,
wherein a plurality of the vapor deposition sources comprise a first vapor deposition source, a second vapor deposition source, and a third vapor deposition source arranged in the first direction, and
wherein the third vapor deposition source is disposed on the opposite side of the first vapor deposition source from the second vapor deposition source in the first direction.

11. The vapor deposition apparatus according to claim 10,
wherein the first vapor deposition source, the second vapor deposition source, and the third vapor deposition source respectively include, on their upper surfaces, a plurality of first vapor deposition source apertures, a plurality of second vapor deposition source apertures, and a plurality of third vapor deposition source apertures, and
wherein the plurality of first vapor deposition source apertures, the plurality of second vapor deposition source apertures, and the plurality of third vapor deposition source apertures are arranged at a constant pitch along a straight-line parallel to a second direction, the second direction being one of the in-plane directions and orthogonal to the first direction.

12. The vapor deposition apparatus according to claim 11,
wherein the second vapor deposition source apertures are inclined such that their opening direction is directed toward the first vapor deposition source apertures, and the third vapor deposition source apertures are also inclined such that their opening direction is directed toward the first vapor deposition source apertures.

13. The vapor deposition apparatus according to claim 11,
wherein first vapor deposition particles are configured to be emitted from the first vapor deposition source apertures, the first vapor deposition particles being vapor of a host included in the light-emitting layer,
second vapor deposition particles are configured to be emitted from the second vapor deposition source apertures, the second vapor deposition particles being vapor of a first dopant included in the light-emitting layer, and
third vapor deposition particles are configured to be emitted from the third vapor deposition source apertures, the third vapor deposition particles being vapor of a second dopant included in the light-emitting layer.

14. The vapor deposition apparatus according to claim 13,
wherein the first dopant and the second dopant are different materials.

15. The vapor deposition method according to claim 8, wherein, before forming the film, the substrate is subjected to baking treatment under reduced pressure and then to oxygen plasma treatment.

16. The vapor deposition method according to claim 8, the method further comprising:
the step of forming a hole injection layer and a hole transport layer over the substrate, the hole injection layer and the hole transport layer being formed over an entire display region of the substrate with an open mask having an aperture extending over the entire display region;
the step of forming light-emitting layers having a strip shape over the hole transport layer with the vapor deposition mask; and
the step of forming an electron transport layer over the hole transport layer and light-emitting layers, the electron transport layer being formed over the entire display region with the open mask.
